(19) United States
(12) Patent Application Publication
(10) Pub. No.: US 2026/0020419 A1
(43) Pub. Date: Jan. 15, 2026

(54) DISPLAY DEVICE, METHOD FOR MANUFACTURING DISPLAY DEVICE AND ELECTRONIC DEVICE

(71) Applicant: Samsung Display Co., LTD., Yongin-si (KR)

(72) Inventors: So Young LEE, Yongin-si (KR); Ki Bum KIM, Yongin-si (KR); Tae Gyun KIM, Yongin-si (KR)

(21) Appl. No.: 19/078,141

(22) Filed: Mar. 12, 2025

(30) Foreign Application Priority Data
Jul. 10, 2024 (KR) 10-2024-0090894

(51) Int. Cl. H10H 29/85; H10H 29/01; H10H 29/14; H10H 29/80; H10H 29/856

(52) U.S. Cl. CPC H10H 29/857; H10H 29/032; H10H 29/0363; H10H 29/0364; H10H 29/142; H10H 29/8322; H10H 29/856

(57) ABSTRACT

A display device a method for manufacturing the same and the electronic device are provided. The display device includes a substrate, connection electrodes above the substrate, light-emitting elements respectively above the connection electrodes, and including a semiconductor stack including a first semiconductor layer, an active layer, and a second semiconductor layer, an etch-stop layer above the semiconductor stack, and an insulating layer surrounding a side surface of the semiconductor stack in plan view, and having one end substantially level with a top surface of the etch-stop layer, and a common electrode above the light-emitting elements.

### CROSS-REFERENCE TO RELATED APPLICATION

The present application claims priority to, and the benefit of, Korean Patent Application No. 10-2024-0090894, filed on Jul. 10, 2024, in the Korean Intellectual Property Office, the entire disclosure of which is incorporated herein by reference.

### BACKGROUND

### 1. Field

The present disclosure relates to a display device, a method for manufacturing the same, and an electronic device.

### 2. Description of the Related Art

With the advancement of multimedia, display devices have become increasingly important. Accordingly, various types of display devices, such as an organic light-emitting diode (OLED) display device and a liquid crystal display (LCD) device, have been developed.

A display panel, such as an organic light-emitting diode display panel and a liquid crystal display panel, is part of a display device for displaying an image. The display device may include a light-emitting element to have a light-emitting display panel. For example, the light-emitting element may be a light-emitting diode (LED) including an organic light-emitting diode (OLED) that uses an organic material as a light-emitting material or an inorganic light-emitting diode that uses an inorganic material as a light-emitting material.

### SUMMARY

Aspects of embodiments of the present disclosure are to provide a display device and a method for manufacturing a display device according to embodiments, which may reduce process mask and reduce or minimize damage to the side of a light-emitting element due to mask misalignment.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a substrate, connection electrodes above the substrate, light-emitting elements respectively above the connection electrodes, and including a semiconductor stack including a first semiconductor layer, an active layer, and a second semiconductor layer, an etch-stop layer above the semiconductor stack, and an insulating layer surrounding a side surface of the semiconductor stack in plan view, and having one end substantially level with a top surface of the etch-stop layer, and a common electrode above the light-emitting elements.

The etch-stop layer may include Indium Tin Oxide (ITO), Indium Zinc Oxide (IZO), or a transparent conductive material.

The etch-stop layer may include AlGaN.

The display device may further include a protective layer surrounding the light-emitting elements, the connection electrodes, and the insulating layer in plan view, and a reflective layer surrounding the light-emitting elements, the connection electrodes, and the protective layer in plan view.

One end of the protective layer and one end of the reflective layer may be substantially level with a top surface of the etch-stop layer.

The display device may further include a trench contacting the common electrode between respective ones of the light-emitting elements so as not to overlap the light-emitting elements.

The trench may include a material having a lower resistivity than the common electrode.

The substrate may include a display area and a non-display area, wherein the common electrode is commonly connected to the light-emitting elements, and wherein the display device further includes a common connection electrode including a same material as the connection electrode at the non-display area of the substrate, and a through electrode electrically between the common connection electrode and the common electrode, connected to the common connection electrode, and including a same material as the trench.

The connection electrodes may include a first connection electrode and a second connection electrode.

The light-emitting elements may further include a contact electrode between the connection electrodes and the semiconductor stack.

The display device may further include a lens-shaped optical structure above the light-emitting elements and the common electrode.

According to one or more embodiments of the present disclosure, a method of manufacturing a display device includes bonding a backplane substrate including a first connection electrode layer with a base substrate having a second connection electrode layer and a semiconductor stack, forming an etch-stop layer on a top surface of the semiconductor stack, etching and dividing the semiconductor stack and the etch-stop layer using a first mask, forming an element-insulating layer covering a top surface of the etch-stop layer and a side surface of the semiconductor stack, polishing a top surface of the base substrate to expose an entire surface of one side of the etch-stop layer, and forming a common electrode above the semiconductor stack.

The method may further include forming a protective layer covering the element-insulating layer, and forming a reflective layer covering the protective layer.

Exposing the entire surface of the one side of the etch-stop layer may include etching the element-insulating layer, the protective layer, and the reflective layer above a top surface of the semiconductor stack by a chemical mechanical polishing (CMP) process.

The polishing the top surface of the base substrate may include forming an organic layer surrounding light-emitting elements in plan view, planarizing the light-emitting elements, and forming a through electrode penetrating the organic layer, and electrically connected to a common connection electrode in a non-display area of the base substrate.

The forming the through electrode may include forming a groove between respective ones of the light-emitting elements in the display area of the base substrate, and filling the groove with a material having a lower resistivity than the common electrode to form a trench.

The etch-stop layer may include Indium Tin Oxide (ITO), Indium Zinc Oxide (IZO), or a transparent conductive material.

The bonding the backplane substrate with the base substrate may include forming the first connection electrode layer on the backplane substrate, forming the second connection electrode layer on the semiconductor stack of the base substrate, arranging the first connection electrode layer and the second connection electrode layer to be in contact, bonding the first connection electrode layer and the second connection electrode layer, and removing the base substrate from the semiconductor stack.

The method may further include forming a lens-shaped optical structure above light-emitting elements, which include the etch-stop layer and the semiconductor stack, and a light-emitting element layer, which includes the common electrode.

According to one or more embodiments of the present disclosure, a method of manufacturing a display device includes bonding a backplane substrate including a first connection electrode layer, and a base substrate including a second connection electrode layer, a semiconductor stack, and an etch-stop layer, etching and dividing the semiconductor stack and the etch-stop layer using a first mask, forming an element-insulating layer to cover a top surface of the etch-stop layer and a side surface of the semiconductor stack, polishing a top surface of the base substrate to expose an entire surface of one side of the etch-stop layer, and forming a common electrode above the semiconductor stack, wherein the etch-stop layer and the semiconductor stack include an AlGaN/GaN double heterostructure.

According to one or more embodiments of the present disclosure, an electronic device includes a substrate, connection electrodes above the substrate, light-emitting elements respectively above the connection electrodes, and including a semiconductor stack including a first semiconductor layer, an active layer, and a second semiconductor layer, an etch-stop layer above the semiconductor stack, and an insulating layer surrounding a side surface of the semiconductor stack in plan view, and having one end substantially level with a top surface of the etch-stop layer, and a common electrode above the light-emitting elements.

According to the display device and the method for manufacturing a display device, a mask is not used during a process for contact between a light-emitting element and a common electrode, and thus, damage to the side of a light-emitting element due to mask may be reduced or prevented.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments.

FIG. 2 is a plan view illustrating one or more embodiments of area A of FIG. 1.

FIG. 3 is a cross-sectional view illustrating one or more embodiments of a cross-section of the display panel taken along the line I-I′ in FIG. 2.

FIG. 4 is an enlarged cross-sectional view illustrating an example of area A of FIG. 3.

FIG. 5 is a cross-sectional view illustrating the shape of the light-emitting element and common electrode of FIG. 3.

FIG. 6 is a cross-sectional view illustrating a light-emitting element according to one or more embodiments.

FIG. 7 is a cross-sectional view illustrating a light-emitting element according to one or more embodiments.

FIG. 8 is a cross-sectional view illustrating a light-emitting element according to one or more embodiments.

FIG. 9 is a cross-sectional view illustrating one or more embodiments of a cross-section of a display panel taken along the line I-I′ of FIG. 2 according to another modified example.

FIG. 10 a flowchart illustrating a method of manufacturing a display panel according to one or more embodiments.

FIGS. 11 to 23 are drawings to illustrate a method for manufacturing a display panel according to one or more embodiments.

FIG. 24 is drawings to illustrate a method for manufacturing a display panel according to one or more other embodiments.

FIGS. 25 and 26 are cross-sectional views to illustrate one or more other embodiments of operations S140 and S150 of FIG. 10.

FIG. 27 is a drawing illustrating a virtual reality device 1 including a display device according to one or more embodiments.

FIG. 28 is a drawing illustrating a smart device including a display device 10_2 according to one or more embodiments.

FIG. 29 is a drawing illustrating an automobile instrument panel and center fascia including display devices according to one or more embodiments.

FIG. 30 is a drawing illustrating a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

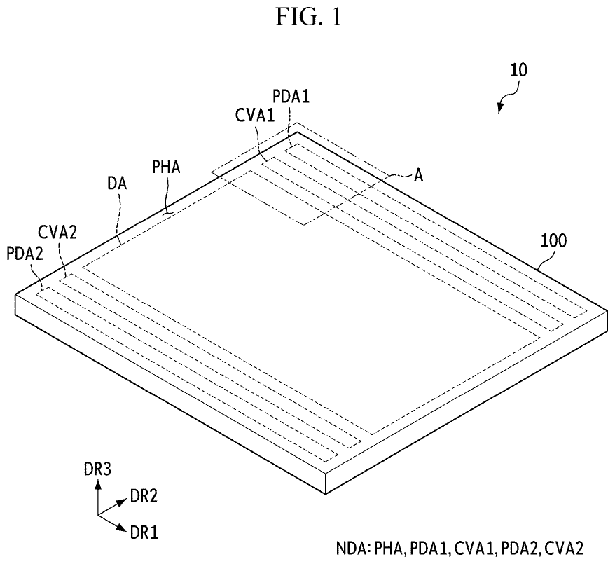

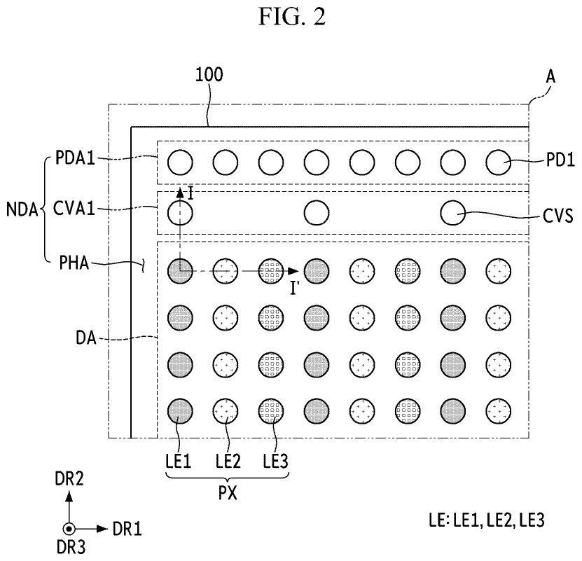

FIG. 1 is a perspective view illustrating a display device according to one or more embodiments. FIG. 2 is a plan view illustrating one or more embodiments of area A of FIG. 1.

FIGS. 1 and 2 illustrate one or more embodiments in which the display device 10 is an LEDoS (Light Emitting Diode on Silicon) in which light-emitting diodes are located as light-emitting elements LE on a semiconductor circuit board formed by a semiconductor process using a silicon wafer (e.g., a backplane substrate 110 of the display panel 100 on which a pixel circuit PXC or the like is formed based on a silicon wafer). However, devices including light-emitting elements LE according to embodiments are not limited thereto. For example, the light-emitting elements LE manufactured according to embodiments may be applied to display devices of different types and/or structures or may be applied to devices of different types and/or structures, such as lighting devices, etc.

In FIGS. 1 and 2, the first direction DR1 may indicate a horizontal direction of the display panel 100, and the second direction DR2 may indicate a vertical direction of the display panel 100. The third direction DR3 may indicate a thickness direction of the display panel 100.

First, referring to FIGS. 1 and 2, the display device 10 according to one or more embodiments may include a display panel 100 including a display area DA and a non-display area NDA.

The display panel 100 may have a rectangular planar shape with a long side in the first direction DR1 and a short side in the second direction DR2. However, the planar shape of the display panel 100 is not limited to this, and the display panel 100 may have other shape. For example, the display panel 100 may have a polygonal, circular, elliptical, or other non-rectangular planar shape other than a rectangular shape.

The display area DA may be an area where an image is displayed, and the non-display area NDA may be an area where the image is not displayed. In one or more embodiments, the planar shape of the display area DA may follow the planar shape of the display panel 100. In FIG. 1, the planar shape of the display area DA is illustrated as a rectangle. The display area DA may be located in the central area of the display panel 100. The non-display area NDA may be located around the display area DA. In one example, the non-display area NDA may surround the display area DA (e.g., as used herein, “surround” may mean “surround in plan view”).

The display area DA may include a plurality of pixels PX. Each pixel PX may include at least two light-emitting elements LE.

In one or more embodiments, each pixel PX may include three light-emitting elements LE. For example, each pixel PX may include a first light-emitting element LE1, a second light-emitting element LE2, and a light-emitting element LE3. The number and/or type of light-emitting elements LE provided to the pixels PX may be varied in different embodiments.

In one or more embodiments, each pixel PX may include light-emitting elements LE that emit light of different colors. For example, the first light-emitting element LE1, the second light-emitting element LE2, and the light-emitting element LE3 may emit light of different colors.

The first light-emitting element LE1 may emit a first light. The first light may be red light. For example, the main peak wavelength (R-peak) of the first light may be located at approximately 600 nm to approximately 750 nm, but embodiments are not limited thereto.

The second light-emitting element LE2 may emit a second light. The second light may be green light. For example, the main peak wavelength (G-peak) of the second light may be located at approximately 480 nm to approximately 560 nm, but embodiments are not limited thereto.

The third light-emitting element LE3 may emit a third light. The third light may be blue light. For example, the main peak wavelength (B-peak) of the third light may be located at approximately 370 nm to approximately 460 nm, but embodiments are not limited thereto.

In one or more other embodiments, the first light-emitting element LE1, the second light-emitting element LE2, and the light-emitting element LE3 may emit light of the same color as each other. A light conversion layer, which may include a light conversion element (e.g., a quantum dot) for converting the color of light (or a wavelength band corresponding thereto) emitted from the at least one light-emitting element LE into light of another color (or a wavelength band corresponding thereto), may be located on at least one light-emitting element LE among the first light-emitting element LE1, the second light-emitting element LE2, and the light-emitting element LE3, the color of light emitted from the at least one light-emitting element LE.

In one or more embodiments, the first light-emitting element LE1, the second light-emitting element LE2, and the light-emitting element LE3 of each pixel PX may be sequentially located in the first direction DR1. In one or more embodiments, the first light-emitting elements LE1 may be arranged in the second direction DR2. The second light-emitting elements LE2 may be arranged in the second direction DR2. The third light-emitting elements LE3 may be arranged in the second direction DR2. For example, in each pixel column extending along the second direction DR2, the first light-emitting element LE1, the second light-emitting element LE2, or the third light-emitting element LE3 may be arranged. In addition, the pixels PX, and the arrangement structure of the light-emitting elements LE provided in the pixels PX, may be varied in different embodiments.

In one or more embodiments, the light-emitting elements LE may be arranged in the display area DA at substantially equal intervals, but is not limited thereto. For example, the positions and/or array spacing of the light-emitting elements LE may be varied depending on the embodiments.

In one or more embodiments, the sizes (e.g., areas) of the light-emitting elements LE may be substantially the same as each other. For example, the first light-emitting element LE1, the second light-emitting element LE2, and the light-emitting element LE3 may have substantially the same size. However, the embodiments are not limited to this, and the size of each light-emitting element LE and/or the area of the light-emitting areas corresponding to the light-emitting elements LE may be varied in different embodiments.

In one or more embodiments, the light-emitting elements LE may have a circular planar shape, but the embodiments are not limited thereto. For example, the light-emitting elements LE may have a rectangular shape or another polygonal shape, an elliptical shape, or any other polygonal, elliptical, or irregular shape. Further, the light-emitting elements LE may have substantially the same planar shape as each other or may have different planar shapes for each group.

The non-display area NDA may include a first common voltage supply area CVA1, a second common voltage supply area CVA2, a first pad area PDA1, a second pad area PDA2, and a peripheral area PHA.

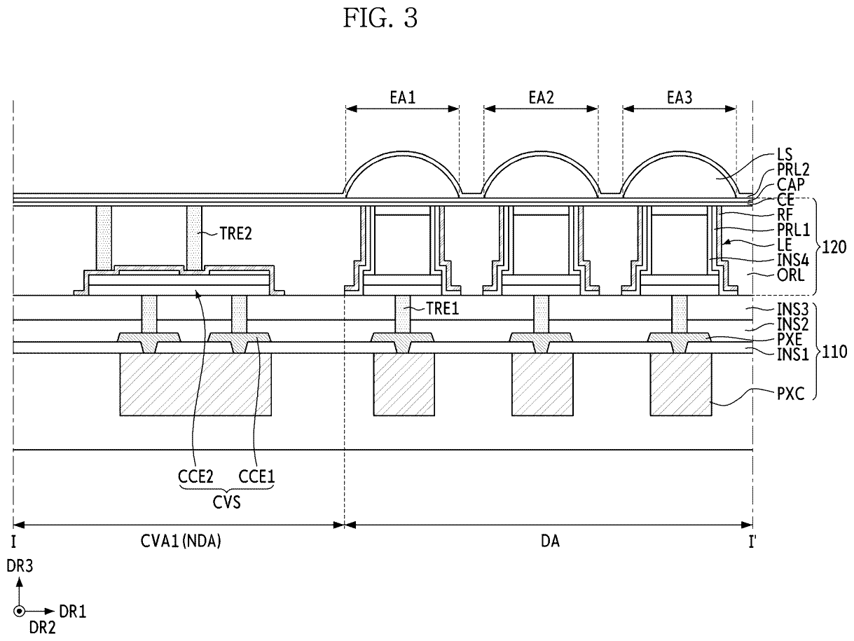

The first common voltage supply area CVA1 may be located between the first pad area PDA1 and the display area DA. The second common voltage supply area CVA2 may be located between the second pad area PDA2 and the display area DA. Each of the first common voltage supply area CVA1 and the second common voltage supply area CVA2 may include common electrode connecting portions CVS connected to a common electrode (e.g., the common electrode CE of FIG. 3). For example, the common electrode may extend from the display area DA to the first common voltage supply area CVA1 and the second common voltage supply area CVA2, and may be electrically connected to the common electrode connecting portions CVS. A common voltage may be supplied to the common electrode through the common electrode connecting portions CVS.

The common electrode connecting portions CVS may be located in a common voltage supply area (e.g., the first common voltage supply area CVA1 and/or the second common voltage supply area CVA2) of the non-display area NDA. The common electrode connecting portions CVS may include a conductive material (e.g., a metal material such as aluminum (Al)). While FIGS. 1 and 2 illustrate the display device 10 in which the common electrode connecting portions CVS are located in the non-display area NDA, but the embodiments are not limited thereto. For example, the common electrode connecting portions CVS may be located in the display area DA. In one example, the common electrode connecting portions CVS may be located in pixel areas or between pixel areas.

The common electrode connecting portions CVS of the first common voltage supply area CVA1 may be electrically connected to one of the first pads PD1 of the first pad area PDA1. For example, the common electrode connecting portions CVS of the first common voltage supply area CVA1 may be supplied with a common voltage from one of the first pads PD1 of the first pad area PDA1.

The first pads PD1 may be located in the first pad area PDA1. The first pads PD1 may be electrically connected to a circuit board CB through a conductive connection member. For example, the first pads PD1 may be electrically connected to a circuit pad provided on a circuit board through wires.

The common electrode connecting portions CVS of the second common voltage supply area CVA2 may be electrically connected to any one of the second pads of the second pad area PDA2. For example, the common electrode connecting portions CVS of the second common voltage supply area CVA2 may receive a common voltage from any one of the second pads of the second pad area PDA2. In one or more embodiments, the display panel 100 may not include the second common voltage supply area CVA2.

The first pad area PDA1 may be located on one side (e.g., the upper side) of the display panel 100. The first pad area PDA1 may include first pads PD1 connected to an external circuit board.

The second pad area PDA2 may be located on another side (e.g., the lower side) of the display panel 100. The second pad area PDA2 may include second pads connected to an external circuit board. In one or more embodiments, the display panel 100 may not include the second pad area PDA2.

The second pads may be located in the second pad area PDA2 of the non-display area NDA. The second pads may be connected to the circuit board through a conductive connection member. For example, the second pads may be electrically connected to circuit pads provided on the circuit board through wires.

The peripheral area PHA may be the non-display area NDA excluding the first common voltage supply area CVA1, the second common voltage supply area CVA2, the first pad area PDA1, and the second pad area PDA2. The peripheral area PHA may surround (e.g., in plan view) the display area DA, as well as the first common voltage supply area CVA1, the second common voltage supply area CVA2, the first pad area PDA1, and the second pad area PDA2.

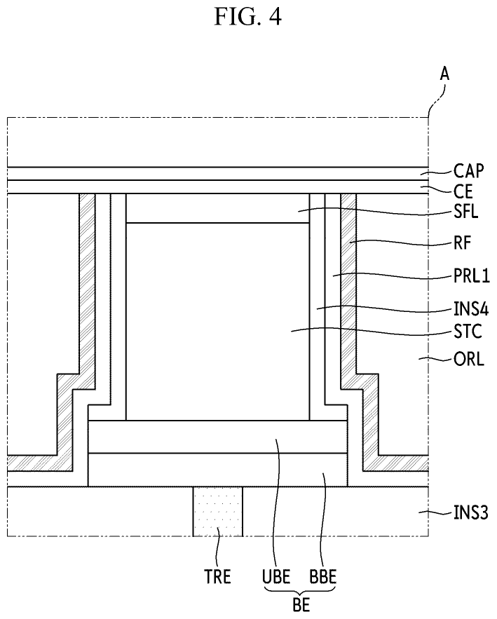

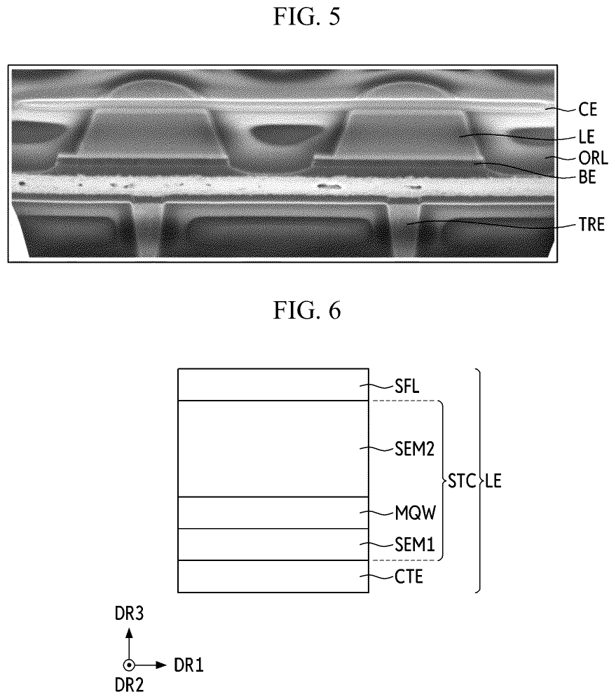

FIG. 3 is a cross-sectional view illustrating one or more embodiments of a cross-section of the display panel taken along the line I-I′ in FIG. 2. FIG. 4 is an enlarged cross-sectional view illustrating an example of area A of FIG. 3. FIG. 5 is a cross-sectional view illustrating the shape of the light-emitting element and common electrode of FIG. 3.

Referring to FIGS. 3 and 4, the display panel 100 may include a display area DA and a non-display area NDA.

The display panel 100 may include a backplane substrate 110 and a light-emitting element layer 120 in the display area DA. In one or more embodiments, the display panel 100 may further include an optical structure (or light-emitting structure), for example, a lens-type optical structure LS, provided on the light-emitting element layer 120.

The display panel 100 may further include additional components according to embodiments. For example, the display panel 100 may further include a light conversion layer for converting the color and/or wavelength of light emitted from at least some of the light-emitting elements LE, and/or a color filter layer for controlling that light of a corresponding color is emitted from each of the light-emitting area EA.

The display panel 100 may include light-emitting areas EA located in the display area DA. Each of the light-emitting areas EA may include at least one light-emitting element LE. For example, the light-emitting areas EA may include a first light-emitting area EA1 provided with at least one first light-emitting element LE1, a second light-emitting area EA2 provided with at least one second light-emitting element LE2, and/or a third light-emitting area EA3 provided with at least one third light-emitting element LE3. In one or more embodiments, first light, second light, and third light may be emitted from the first light-emitting area EA1, the second light-emitting area EA2, and the third light-emitting area EA3, respectively.

The backplane substrate 110 may include a display area DA including light-emitting areas EA. In one or more embodiments, the backplane substrate 110 may be a semiconductor circuit board formed through a semiconductor process using a silicon wafer. For example, a silicon wafer may be used as a base member to form the display panel 100.

The backplane substrate 110 may include pixel circuits PXC and pixel electrodes PXE provided in the display area DA. For example, at least one light-emitting element LE may be provided in each light-emitting area EA of the display panel 100, and the backplane substrate 110 may include pixel circuits PXC and pixel electrodes PXE connected (e.g., electrically connected) to each of the light-emitting elements LE located in the respective light-emitting areas EA.

In one or more embodiments, the backplane substrate 110 may further include a first insulating layer INS1 located around the pixel electrodes PXE.

The pixel circuits PXC may be provided in the display area DA corresponding to the area where each pixel PX and/or the light-emitting areas EA are formed. In one or more embodiments, each of the pixel circuits PXC may include a complementary metal-oxide semiconductor (CMOS) circuit formed using a semiconductor process.

Each of the pixel circuits PXC may include at least one transistor formed through a semiconductor process. Additionally, each of the pixel circuits PXC may further include at least one capacitor formed through a semiconductor process.

The pixel circuits PXC may be electrically connected to each pixel electrode PXE. For example, the pixel circuits PXC and the pixel electrodes PXE may be connected in a one-to-one correspondence. Each of the pixel circuits PXC may apply a pixel voltage to the pixel electrode PXE connected thereto.

The pixel electrodes PXE may be connected to each pixel circuit PXC. The pixel electrodes PXE may be individually provided in each light-emitting area EA and electrically connected to the light-emitting elements LE located in each light-emitting area EA. Accordingly, the light-emitting elements LE located in each light-emitting area EA may be individually and/or independently controlled.

Each of the pixel electrodes PXE may be located on the corresponding pixel circuit PXC. In one or more embodiments, each of the pixel electrodes PXE may be formed integrally with the pixel circuit PXC, and may be an electrode exposed from the pixel circuit PXC. For example, each of the pixel electrodes PXE may protrude from a top surface of the pixel circuit PXC. Each of the pixel electrodes PXE may receive a pixel voltage from the pixel circuit PXC. The pixel electrodes PXE may include a conductive material (e.g., a metal material such as aluminum (Al)).

In one or more embodiments, the first insulating layer INS1 may be located around the pixel electrodes PXE. The first insulating layer INS1 may be provided on a top surface of the semiconductor circuit board on which the pixel circuits PXC are formed. In one or more embodiments, the first insulating layer INS1 may be located between the pixel electrodes PXE to surround the pixel electrodes PXE (e.g., in plan view).

The first insulating layer INS1 may expose at least a portion of each of the pixel electrodes PXE. For example, the first insulating layer INS1 may include openings corresponding to the pixel electrodes PXE, and may expose the top surface of the pixel circuits PXC. The first insulating layer INS1 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or other insulating material.

The non-display area NDA may further include the common voltage supply area CVA1.

In one or more embodiments, the backplane substrate 110 may include the common electrode connecting portions CVS located in the common voltage supply area CVA1.

In one or more embodiments, the the common electrode connecting portions CVS may include a first common connection electrode CCE1 and a second common connection electrode CCE2.

The first common connection electrode CCE1 and the pixel electrodes PXE may be formed by the same process. Accordingly, the first common connection electrode CCE1 may include the same material as the pixel electrodes PXE, and the first common connection electrode CCE1 and the pixel electrodes PXE may have substantially the same thickness in the third direction DR3.

The second common connection electrode CCE2 may be located on the first common connection electrode CCE1. The second common connection electrode CCE2 and the connection electrodes UBE and BBE may be formed by the same process. Therefore, the second common connection electrode CCE2 may be formed in multiple layers. For example, the second common connection electrode CCE2 may include a second common connection electrode CCE2 in a lower layer, and a second common connection electrode CCE2 in an upper layer. The second common connection electrode CCE2 in the lower layer may be located in the same layer as the first connection electrode BBE, and the second common connection electrode CCE2 in the upper layer may be located in the same layer as the second connection electrode UBE. The second common connection electrode CCE2 may include the same material as the connection electrodes UBE and BBE, and the second common connection electrode CCE2 and the connection electrodes UBE and BBE may have substantially the same thickness in the third direction DR3.

The light-emitting element layer 120 may include connection electrodes UBE and BBE, light-emitting elements LE, a fourth insulating layer INS4, and a common electrode CE. In one or more embodiments, the light-emitting element layer 120 may further include additional configurations. For example, the light-emitting element layer 120 may further include a first protective layer PRL1, a reflective layer RF, and/or a light-blocking layer provided between the light-emitting elements LE and/or on the side of the light-emitting elements LE, an organic layer ORL located around the light-emitting elements LE, and/or a capping layer CAP located on the common electrode CE.

The connection electrodes UBE and BBE may be provided at positions corresponding to the respective pixel electrodes PXE, and may be electrically connected to the respective pixel electrodes PXE. For example, the connection electrodes UBE and BBE may be located on the respective pixel electrodes PXE.

In one or more embodiments, the connection electrode BE may include a first connection electrode BBE and a second connection electrode UBE that are sequentially stacked.

The first connection electrode BBE may be located on the second interlayer insulating layer INS3 and a through electrode TRE. The first connection electrode BBE may be connected to the pixel electrode PXE through the through electrode TRE.

The second interlayer insulating layer INS3 may be located on the first interlayer insulating layer INS2.

The first connection electrode BBE and the second connection electrode UBE may include a single layer of conductive material or may be formed as a multilayer. The conductive material may include Ti, Ni, Pt, Sn, Au, Al, and W. For example, the first connection electrode BBE and the second connection electrode UBE may include a barrier layer formed of titanium (Ti), and a connection layer formed of gold (Au) having a low melting point.

In addition, the second connection electrode UBE may include three electrode layers. For example, the upper connection electrode UBE may include a first electrode layer formed of Sn, a second electrode layer formed of Au, and a third electrode layer formed of Ti.

When the first connection electrode BBE and the second connection electrode UBE include connection layers, the connection layer of the first connection electrode BBE and the connection layer of the second connection electrode UBE may face each other.

The light-emitting element LE may be located on the second connection electrode UBE.

One end of the light-emitting element LE may be electrically connected to the pixel electrodes PXE through the connection electrode BE. The other end of the light-emitting element LE may be electrically connected to the common electrode.

The pixel electrodes PXE may be connected to each pixel circuit PXC. The pixel electrodes PXE may be individually provided in each of the light-emitting areas EA, and may be electrically connected to the light-emitting elements LE positioned in each of the light-emitting areas EA. Accordingly, the light-emitting elements LE located in each of the light-emitting areas EA may be individually and/or independently controlled.

Each of the light-emitting elements LE may be positioned on the connection electrode BE. The light-emitting elements LE may be vertical light-emitting diode elements extending in the third direction DR3. That is, the length of the light-emitting element LE in the third direction DR3 may be longer than the length in the horizontal direction. The length in the horizontal direction refers to the length in the first direction DR1 or the length in the second direction DR2.

The light-emitting elements LE may be micro light-emitting diode elements or nano light-emitting diode elements.

The light-emitting elements LE may include a semiconductor stack STC grown on a semiconductor substrate (e.g., a wafer substrate) by epitaxial growth. In addition, the light-emitting elements LE may further include an etch-stop layer SFL on the semiconductor stack STC. The etch-stop layer SFL may be a conductive material.

A detailed description of the structure and manufacturing method of the light-emitting elements LE including the etch-stop layer SFL according to one or more embodiments will be described later.

The side surfaces of the light-emitting elements LE except for one surface of the light-emitting elements LE may be surrounded by a fourth insulating layer INS4 (e.g., in plan view). Further, the fourth insulating layer INS4 may be located on one surface of the connection electrode BE.

The fourth insulating layer INS4 may be formed of an inorganic film, such as silica, a silicon nitride layer, a silicon oxy nitride layer, a silicon oxide layer, a titanium oxide layer, or an aluminum oxide layer.

The first protective layer PRL1 may protect the light-emitting elements LE from an outer side than the fourth insulating layer INS4. The first protective layer PRL1 may surround a side surface of the light-emitting elements LE, and may extend from a side surface of the light-emitting elements LE to a side surface of the connection electrode BE to surround a side surface of the connection electrode BE.

The first protective layer PRL1 may include an inorganic insulating material such as silicon oxide, silicon nitride, silicon oxynitride, or the like.

The reflective layer RF may be located on the first protective layer PRL1. The reflective layer RF surrounds a side surface of the first protective layer PRL1. For example, the reflective layer RF may surround an outer surface of the light-emitting element LE on the first protective layer PRL1, and may surround a side surface of the light-emitting element LE. The reflective layer RF may be insulated from the semiconductor stack STC of the light-emitting element LE and the connection electrode BE by the first protective layer PRL1 and the fourth insulating layer INS4. Furthermore, one end of the reflective layer RF, one end of the first protective layer PRL1, and one end of the fourth insulating layer INS4 may contact the common electrode CE. However, due to a process error, a step difference of about −20 nm to about +20 nm may occur between one end of the fourth insulating layer INS4 and the upper surface of the etch-stop layer SFL. For example, one end of the fourth insulating layer INS4 may be about −20 nm lower than the upper surface of the etch-stop layer SFL.

The reflective layer RF may reflect light emitted from the light-emitting element LE. For example, the reflective layer RF may reflect light emitted from the active layer MQW of the light-emitting element LE to be emitted laterally upward (e.g., in the third direction DR3). That is, the reflective layer RF may improve the light emission efficiency of the light-emitting element LE. To this end, the reflective layer RF may surround at least the side of the active layer MQW of the light-emitting element LE.

The reflective layer RF may include a metal material having high reflectivity. For example, the reflective layer RF may include aluminum or silver, and may also be an alloy thereof.

An organic layer ORL may be provided around the light-emitting elements LE. For example, the organic layer ORL may be located between the light-emitting areas EA in which the light-emitting elements LE are provided to surround the light-emitting areas EA, and may surround the light-emitting elements LE and the connection electrodes BBE and UBE. In one or more embodiments, the organic layer ORL may be a filler that fills a gap between the light-emitting elements LE. The organic layer ORL may expose a portion of the light-emitting elements LE, for example, a top surface. The organic layer ORL flattens a step generated by the light-emitting elements LE.

The organic layer ORL may also be located in the non-display area NDA. In the non-display area NDA, the organic layer ORL may cover the second common connection electrode CCE2.

The organic layer ORL may include an insulating material. For example, the organic layer ORL may be a single layer or multiple layers of an organic insulating film including an acrylic resin, epoxy resin, phenolic resin, polyamide resin, polyimide resin, or other organic insulating material.

Referring to FIGS. 3 to 5, the common electrode CE may be located on the top portion of the light-emitting elements LE that are not covered by the organic layer ORL. In one or more embodiments, the common electrode CE may be located over the entire surface of the display area DA to cover the light-emitting elements LE and the organic layer ORL. The common electrode CE may be a common layer that is commonly formed and/or connected to the light-emitting elements LE of the display area DA and the pixels PX including the light-emitting elements LE.

The common electrode CE may include a transparent conductive material capable of transmitting light. For example, the common electrode CE may be made of indium tin oxide (ITO), indium zinc oxide (IZO), or other transparent conductive materials. In one or more embodiments, it may function as a cathode electrode (or anode electrode) of the light-emitting elements LE.

The common electrode CE may be located up to the common voltage supply area CVA1.

The common electrode CE may be connected to the second common connection electrode CCE2 through a second through-hole electrode TRE2 penetrating the organic layer ORL in the first common voltage supply area CVA1.

The capping layer CAP may be located on the common electrode CE. For example, the capping layer CAP may be located over the entire display area DA to cover the common electrode CE. The capping layer CAP may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or other insulating material.

In one or more embodiments, the display panel 100 may include a lens-type optical structure LS provided on the light-emitting element layer 120. Additionally, the display panel 100 may further include a protective layer PSV covering the lens-type optical structure LS.

The lens-type optical structure LS may be located in each light-emitting area EA to overlap the light-emitting elements LE. In one or more embodiments, the lens-type optical structure LS may be an optical structure in the form of a convex lens provided on top of the light-emitting elements LE, but the type and/or shape of the optical structure is not limited thereto. By positioning the lens-type optical structure LS on top of the light-emitting elements LE, the light output characteristics of the pixels PX may be adjusted and/or improved.

The lens-type optical structure LS may be formed of a transparent material to allow light incident from the light-emitting elements LE to be transmitted. For example, the lens-type optical structure LS may be formed of glass, plastic, ceramic, or other materials, and may be formed of an optical material with a high refractive index.

The second protective layer PSV2 may be located on the lens-type optical structure LS to cover the lens-type optical structure LS. The second protective layer PSV2 may be formed of a transparent and durable material (e.g., plastic or organic glass, optical glass, ceramic, etc.), but is not particularly limited thereto, as long as the material is suitable for protecting the lens-type optical structure LS. Although FIG. 3 illustrates one or more embodiments in which the second protective layer PSV2 has a curve corresponding to the shape of the lens-type optical structure LS, the embodiments are not limited thereto. For example, the second protective layer PSV2 may be formed in a shape that may planarize the top surface of the display panel 100 on which the lens-type optical structure LS is formed.

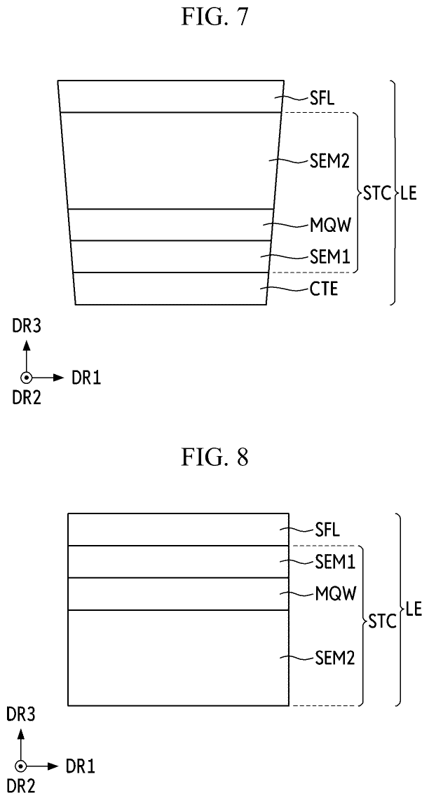

FIG. 6 is a cross-sectional view illustrating a light-emitting element according to one or more embodiments. FIG. 7 is a cross-sectional view illustrating a light-emitting element according to one or more embodiments. FIG. 8 is a cross-sectional view illustrating a light-emitting element according to one or more embodiments. For example, FIG. 7 illustrates one or more embodiments that is different from the one or more embodiments corresponding to FIG. 6 with respect to the shape of the light-emitting element LE, and FIG. 8 illustrates one or more embodiments that is different from the one or more embodiments corresponding to FIG. 6 with respect to the arrangement direction of the light-emitting element LE.

Referring to FIGS. 6 to 8, the light-emitting element LE includes a semiconductor stack STC. The semiconductor stack STC may include a first semiconductor layer SEM1, an active layer MQW, and a second semiconductor layer SEM2 sequentially located and/or stacked along the third direction DR3. The semiconductor stack STC may further include additional layers according to other embodiments. For example, the light-emitting element LE may further include an electron-blocking layer located between the first semiconductor layer SEM1 and the active layer MQW, and/or a superlattice layer located between the active layer MQW and the second semiconductor layer SEM2.

In one or more embodiments, the light-emitting element LE further includes an etch-stop layer SFL provided at one end. In addition, the light-emitting element LE may further include a contact electrode CTE at one end. For example, the light-emitting element LE may further include a contact electrode CTE provided at one end where the first semiconductor layer SEM1 is located.

In one or more embodiments, the light-emitting element LE may be an inorganic light-emitting element made of an inorganic material. For example, the light-emitting element LE may be an inorganic light-emitting diode formed from a nitride-based semiconductor material such as GaN, AlGaN, InGaN, AlInGaN, AlN or InN, a phosphide-based semiconductor material such as GaP, GaInP, AlGaP, AlGaInP, AlP or InP, or any other inorganic material.

The etch-stop layer SFL may be provided and/or formed on a top surface of the semiconductor stack STC. For example, the etch-stop layer SFL may be provided and/or formed on one surface of the second semiconductor layer SEM2.

The etch-stop layer SFL may protect the second semiconductor layer SEM2 and may be an electrode for smooth connection to the common electrode CE. The etch-stop layer SFL may include a metal, a metal oxide, or other conductive material. The etch-stop layer SFL may include a transparent conductive material. For example, the etch-stop layer SFL may be made of indium tin oxide (ITO), indium zinc oxide (IZO), or other transparent conductive materials.

The contact electrode CTE may be provided and/or formed at one end of the light-emitting element LE where the first semiconductor layer SEM1 is located. For example, the contact electrode CTE may be provided and/or formed on one surface of the first semiconductor layer SEM1. The contact electrode CTE may be an electrode that protects the first semiconductor layer SEM1, and smoothly connects the first semiconductor layer SEM1 to at least one circuit element, electrode, wiring, and/or conductive layer. The contact electrode CTE may include a metal, metal oxide, or other conductive material.

The first semiconductor layer SEM1 may be located on the contact electrode CTE. In one or more embodiments, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, or InN, or a phosphide-based semiconductor material including at least one of GaP, GaInP, AlGaP, AlGaInP, AlP, or InP. The first semiconductor layer SEM1 may include other materials.

The first semiconductor layer SEM1 may include a semiconductor material doped with a first conductivity type dopant. For example, the first semiconductor layer SEM1 may include GaN (e.g., p-type dopant) doped with a first conductive dopant (e.g., p-type dopant), such as Mg, Zn, Ca, Se, Ba, or the like.

The active layer MQW may be located on the first semiconductor layer SEM1. The active layer MQW may emit light by recombination of electron-hole pairs according to an electrical signal applied through the first semiconductor layer SEM1 and the second semiconductor layer SEM2. For example, the active layer MQW may be a light-emitting layer of the light-emitting element LE.

The active layer MQW may include a material with a single or multiple quantum well structure. When the active layer MQW includes a material with a multi-quantum well structure, the active layer MQW may have a structure in which a plurality of well layers and barrier layers are alternately stacked. The active layer MQW may include three to five different semiconductor materials, depending on the wavelength band of the light emitted.

In one or more embodiments, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, or AlInN, or a phosphide-based semiconductor material including at least one of GaP, GaInP, AlGaP, AlGaInP, AlP, or InP. For example, the well layer may be formed of InGaN, and the barrier layer may be formed of GaN or AlGaN, but embodiments are not limited thereto. When the active layer MQW includes InGaN, the color of light emitted from the light-emitting element LE may be controlled by adjusting the content of indium (In). The active layer MQW may also include other materials.

In one or more embodiments, the active layers MQW of the first light-emitting element LE1, the second light-emitting element LE2, and the third light-emitting element LE3 shown in FIGS. 2 and 3 may emit light of the same color (e.g., blue light) as each other. In one or more other embodiments, the active layers MQW of the first light-emitting element LE1, the second light-emitting element LE2, and the third light-emitting element LE3 may emit different respective colors of light (e.g., red light, green light, and blue light, respectively).

The second semiconductor layer SEM2 may be located on the active layer MQW. In one or more embodiments, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, or InN, or a phosphide-based semiconductor material including at least one of GaP, GaInP, AlGaP, AlGaInP, AlP, or InP. The second semiconductor layer SEM2 may also include other materials.

The second semiconductor layer SEM2 may include a semiconductor material doped with a second conductivity type dopant. For example, the second semiconductor layer SEM2 may include GaN (e.g., n-GaN) doped with a second conductive dopant (e.g., n-type dopant), such as Si, Ge, Sn, or the like.

In one or more embodiments, the first semiconductor layer SEM1 and the second semiconductor layer SEM2 may have different respective thicknesses in a thickness direction of the light-emitting element LE (e.g., the third direction DR3). For example, the second semiconductor layer SEM2 may have a larger thickness than the first semiconductor layer SEM1 in the thickness direction of the light-emitting element LE. Accordingly, the active layer MQW may be closer to a first end (for example, a p-type end) of the light-emitting element LE provided with the first semiconductor layer SEM1 than to a second end (for example, an n-type end) of the light-emitting element LE provided with the second semiconductor layer SEM2.

In one or more embodiments, the light-emitting element LE may be a vertical micro-LED extending and/or stacked in the third direction DR3. For example, the light-emitting element LE may be a micro-LED having a length in the first direction DR1, a length in the second direction DR2, and a length in the third direction DR3 of tens to hundreds of micrometers (μm), respectively. In one or more embodiments, the length of the light-emitting element LE in the first direction DR1, the length in the second direction DR2, and the length in the third direction DR3 may each be approximately 100 μm or less.

In one or more embodiments, the light-emitting element LE may include a substantially vertical side surface as illustrated in FIG. 6. For example, the light-emitting element LE may be patterned through vertical etching, and may have a rectangular or square cross-sectional shape in which the width of the top surface and the width of the bottom surface are substantially the same.

The shape of the light-emitting element LE may vary depending on the embodiments. For example, the light-emitting element LE may have a cross-sectional shape in which the width of the top surface and the width of the bottom surface are different.

In one or more embodiments, the light-emitting element LE may have a cross-sectional shape of an inverted taper as illustrated in FIG. 7. For example, the light-emitting element LE may have an inverted trapezoidal cross-sectional shape in which the width of the top surface is wider than the width of the bottom surface.

In one or more embodiments, the light-emitting element LE may be located on the backplane substrate 110 such that the first semiconductor layer SEM1 is located below the active layer MQW and the second semiconductor layer SEM2 is located above the active layer MQW, as shown in FIG. 6. For example, the light-emitting element LE may be located in each light-emitting area EA such that the contact electrode CTE (or the first semiconductor layer SEM1) is in contact with the second connection electrode UBE of FIG. 4, and such that the second semiconductor layer SEM2 (or another contact electrode provided on the second semiconductor layer SEM2) is in contact with the common electrode CE. In this case, the common electrode CE may be a cathode electrode.

In one or more embodiments, the light-emitting element LE may be located on the backplane substrate 110 such that the second semiconductor layer SEM2 is located below the active layer MQW and the first semiconductor layer SEM1 is located above the active layer MQW, as shown in FIG. 8. For example, the light-emitting element LE may be located such that the second semiconductor layer SEM2 (or another contact electrode provided on the second semiconductor layer SEM2) may be in contact with the connection electrode BE of FIG. 3, and the etch-stop layer SFL may be located on the first semiconductor layer SEM1. In this case, the common electrode CE may be an anode electrode.

In one or more embodiments, the side to form the bonding material may be selected by transferring the carrier substrate after forming the semiconductor stack by growing it on the base substrate.

The structure, material, size, and/or shape of the light-emitting element LE are not limited to the embodiments described above. For example, the structure, material, size, and/or shape of the light-emitting element LE may be variously changed depending on the embodiments.

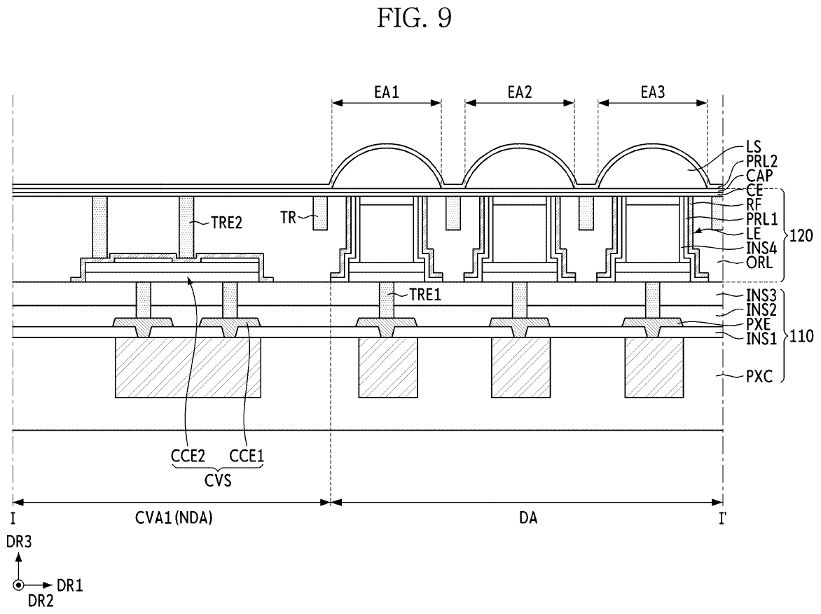

FIG. 9 is a cross-sectional view illustrating one or more embodiments of a cross-section of a display panel taken along the line I-I′ of FIG. 2 according to another modified example.

It is different from the one or more embodiments corresponding to FIG. 3 in that a trench TR is formed in a non-emitting area. The trench TR may be in contact with the common electrode CE, and may be located within the organic layer ORL of the non-emitting area. The trench TR may be spaced apart from the light-emitting element LE.

The trench TR is formed in a mesh type on a plane, and is electrically connected to the common electrode CE. For example, the trench TR overlaps the non-emitting area, and does not overlap the light-emitting area.

In this specification, “on a plane” is set based on a plane parallel to the plane defined by the first direction DR1 and the second direction DR2.

The trench TR is made of a material having a lower resistivity than the common electrode CE. The trench TR may be in contact with the common electrode CE, and may reduce the IR drop of the common electrode CE. Therefore, the luminance unevenness of the display device may be reduced or minimized.

The trench TR may be formed during the same process as a second through electrode TRE2. The trench TR is made of a material having a lower resistivity than the common electrode CE. The trench TR may include at least one material selected from the group consisting of copper (Cu), chromium (Cr), chromium alloys, molybdenum (Mo), molybdenum alloys, and/or oxides thereof (CrOx, MoOx).

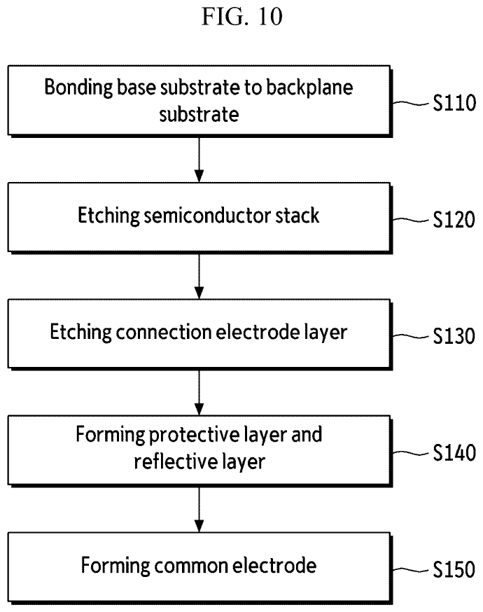

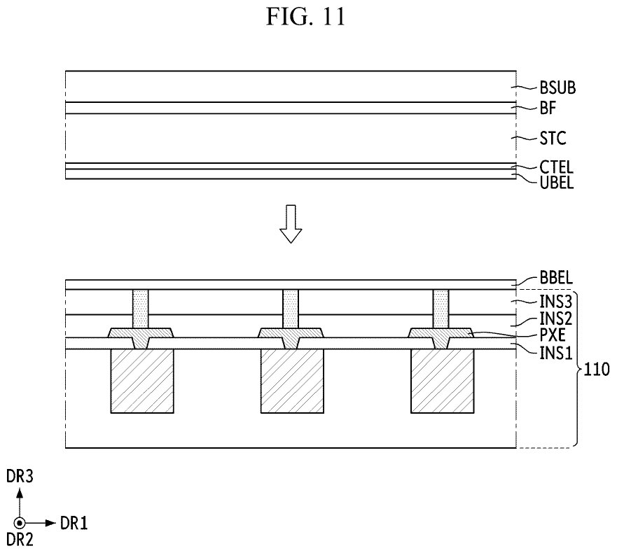

FIG. 10 a flowchart illustrating a method of manufacturing a display panel according to one or more embodiments. For example, FIG. 10 is a flowchart showing a method of manufacturing a display panel 100 of a display device 10 according to one or more embodiments. FIGS. 11 to 23 are drawings to illustrate a method for manufacturing a display panel according to one or more embodiments. For example, each of FIGS. 11 to 21 illustrates, in the form of a cross-sectional view, a corresponding operation for forming a display panel 100.

A base substrate BSUB is bonded to a backplane substrate 110 (S110 of FIG. 10).

Referring to FIG. 11, a first connection electrode BBE is formed on a top portion of the backplane substrate 110, and a second connection electrode layer UBEL is formed on the base substrate BSUB on which a multi-layer semiconductor stack STC is laminated.

For example, a conductive first connection electrode layer BBEL may be formed by applying a conductive bonding material to the entire top surface of the backplane substrate 110. The first connection electrode layer BBEL may be formed as a multi-layer.

In addition, a buffer layer BF may be formed on one surface of the base substrate BSUB. The base substrate BSUB may be a substrate including a material, such as silicon (Si), sapphire, SiC, GaN, GaAs, or ZnO. When the epitaxial growth for manufacturing the light-emitting element LE may be smoothly performed, the type, material, and shape of the base substrate BSUB are not particularly limited.

A multi-layer semiconductor stack STC may be located on the buffer layer BF. The multi-layer semiconductor stack STC may include a first semiconductor layer SEM1, an active layer MQW, a second semiconductor layer SEM2, and a third semiconductor layer SEM3, as shown in FIG. 5.

For example, as shown in FIG. 5, a third semiconductor layer SEM3, a second semiconductor layer SEM2, an active layer MQW, and a first semiconductor layer SEM1 may be sequentially formed through epitaxial growth on the base substrate BSUB. In one or more embodiments, the third semiconductor layer SEM3, the second semiconductor layer SEM2, the active layer MQW, and the first semiconductor layer SEM1 may be formed by epitaxial growth using a process technology, such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

In one or more embodiments, when manufacturing a light-emitting element LE including a contact electrode CTE as in the embodiments of FIGS. 6 and 7, a process may further include forming a contact electrode CTE (or a conductive layer for forming the contact electrode CTE) on a multi-layer semiconductor stack STC. The contact electrode CTE may be formed of a material of the contact electrode CTE previously described. The contact electrode CTE may be formed through a process, such as applying (e.g., depositing) a conductive material on a semiconductor stack STC, and the method of forming the contact electrode CTE is not particularly limited.

One or more layers of second connection electrode layers UBEL may be formed on the top surface of the semiconductor stack STC (or the contact electrode CTE).

For example, a conductive second connection electrode layer UBEL may be formed by applying a second connection electrode material entirely on the top surface of the semiconductor stack STC (or the contact electrode CTE).

Thereafter, the second connection electrode layer UBEL of the base substrate BSUB is located to face the first connection electrode layer BBEL of the backplane substrate 110. Thereafter, the base substrate BSUB may be bonded by placing it on the backplane substrate 110 so that the first connection electrode layer BBEL of the backplane substrate 110 and the second connection electrode layer UBEL of the base substrate BSUB are in contact with each other. Accordingly, the semiconductor stack STC of the base substrate BSUB may be bonded on the backplane substrate 110.

For example, by a bonding process of the base substrate BSUB to the backplane substrate 110 by a thermal compression (TC) bonding method, the first connection electrode layer BBEL of the backplane substrate 110 and the second connection electrode layer UBEL of the base substrate BSUB may be bonded. The bonding (or adhesion) method of the base substrate BSUB to the backplane substrate 110 is not limited thereto, and the backplane substrate 110 and the base substrate BSUB may be bonded by other methods.

The base substrate BSUB may be removed.

For example, a laser beam is irradiated to the base substrate BSUB through a laser device to separate a multi-layer semiconductor stack STC from the base substrate BSUB. The base substrate BSUB is separated from the third semiconductor layer SEM3 of the multi-layer semiconductor stack STC.

The process of separating the base substrate BSUB may be separated by a laser lift off (LLO) process. The laser lift off process uses a laser, and a KrF excimer laser (e.g., about 248 nm wavelength) may be used as a source but is not limited thereto. By irradiating the base substrate BSUB with a laser, the base substrate BSUB may be separated from the multi-layer semiconductor stack STC.

The buffer layer BF and the third semiconductor layer SEM3 may be removed by a polishing process and/or an etching process, such as a chemical mechanical polishing (CMP) process. In addition, the third semiconductor layer SEM3 of the semiconductor stack STC may be removed through a polishing process, such as a CMP process. If suitable, at least a portion of the third semiconductor layer SEM3 of the semiconductor stack STC may be left (see FIG. 6).

An etching stop layer SFL is formed on the top surface of the semiconductor stack STC. The etching stop layer SFL may be formed of, for example, a metal, a metal oxide, or other conductive material. Therefore, the etching stop layer SFL may later serve as a contact electrode.

The semiconductor stack STC is etched using a mask (S120 of FIG. 10).

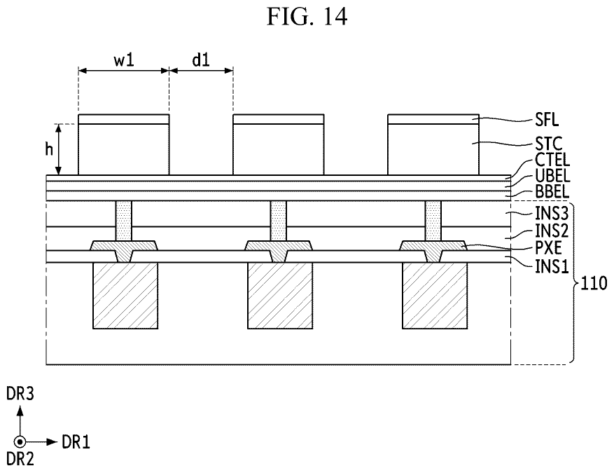

As shown in FIG. 13 and FIG. 14, a mask pattern HM1 is formed on the top surface of the semiconductor stack STC. The mask pattern HM1 may be located in an area where the light-emitting element LE is to be formed.

The etch stop layer SFL and the semiconductor stack STC are etched using the mask pattern (HM1 of FIG. 13). For example, the etch stop layer SFL and the semiconductor stack STC that overlap with the mask pattern HM may not be etched, and the etch stop layer SFL and the semiconductor stack STC that do not overlap with the mask may be etched. If suitable, the mask may use a double mask.

The width W1 of the semiconductor stack STC in the first direction DR1 may be about 1.5 μm, and the separation distance d1 between the semiconductor stacks STC in the first direction DR1 may be about 1.25 μm. Further, the height h of the semiconductor stack STC in the third direction DR3 may be about 1.0 μm +0.1 μm, for example.

The fourth insulating layer INS4 is formed, and the connection electrode layers UBEL and BBEL are etched (S130 of FIG. 10).

The fourth insulating layer INS4 may be referred to as an element-insulating layer INS4 for convenience of description.

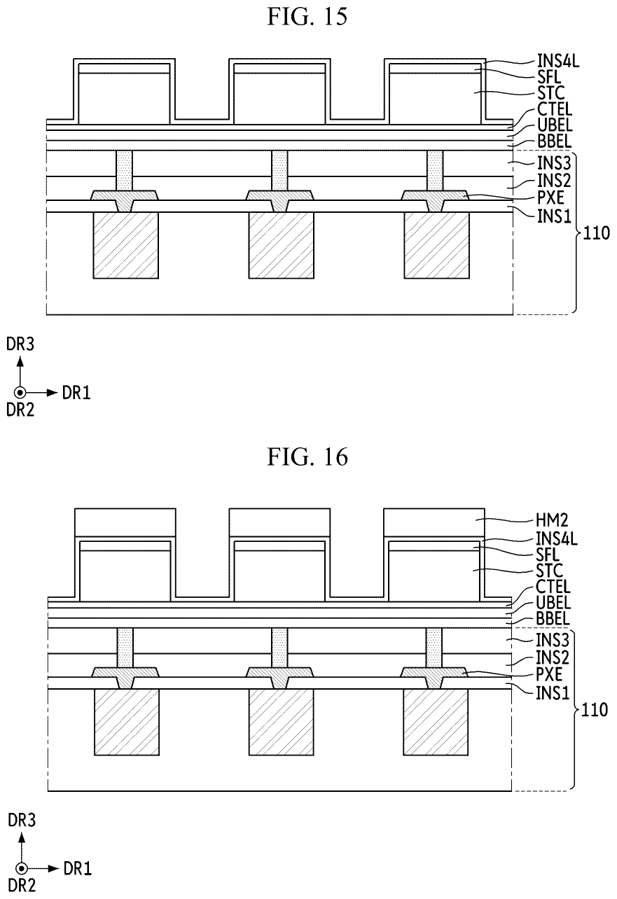

Referring to FIG. 15, the element-insulating layer INS4 is formed by applying an insulating material INS4L to the entire surface of the backplane substrate 110 on which a plurality of semiconductor stacks STC are etched. The fourth insulating layer INS4 may be applied to surround both the side surfaces of the plurality of semiconductor stacks STC and the top surface of the etching stop layer. The fourth insulating layer INS4 may be formed on the lower structure with the same thickness.

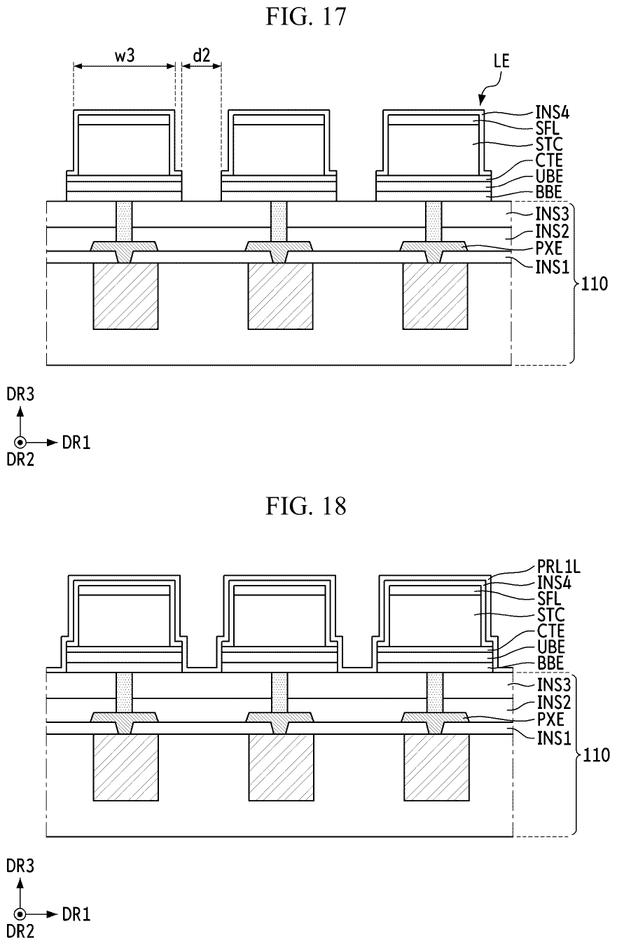

Referring to FIG. 16 and FIG. 17, a mask pattern HM2 may be used to etch the first connection electrode layer BBEL and the second connection electrode layer UBEL. The process of etching the first connection electrode layer BBEL and the second connection electrode layer UBEL may be similar to the process of etching the semiconductor stack. The first connection electrode BBE and the second connection electrode UBE formed in this manner may protrude outwardly from the semiconductor stack STC. The gap d2 between the neighboring connection electrodes UBE and BBE may be about 0.76 μm, and the gap d3 between the neighboring light-emitting elements LE may be about 2 μm, but is not limited thereto.

Accordingly, an element-insulating layer INS4 is located on the upper surface of the first connection electrode BBE and the second connection electrode UBE protruding outwardly from the semiconductor stack STC, while the element-insulating layer INS4 is not located on the side surface of the first connection electrode BBE and the second connection electrode UBE, and may be exposed.

The first protective layer PRL1 and the reflection layer RFL are formed (S140 of FIG. 10).

As shown in FIG. 18, an inorganic insulating material is applied to the entire backplane substrate 110 to cover the sides of the connection electrodes UBE and BBE and the element-insulating layer INS4 to form the first protective layer PRL1.

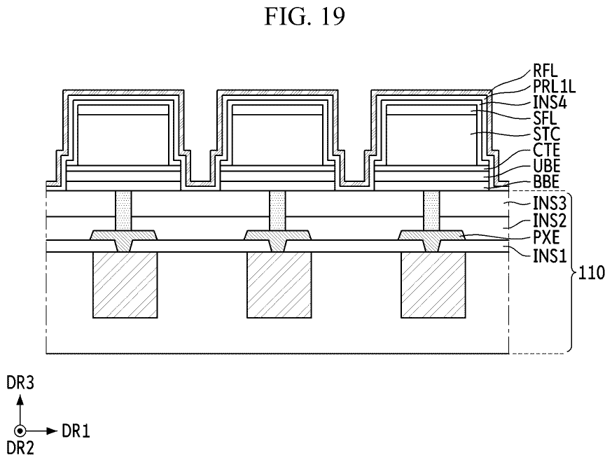

As shown in FIG. 19, a metal material is applied to the entire backplane substrate 110 to cover the entire first protective layer PRL1 to form the reflective layer RFL. The metal material may include, but is not limited to, aluminum or silver, for example.

In one or more other embodiments, operation S140 may be omitted.

The top surface of the light-emitting element LE is polished to expose it, and a common electrode CE is formed (S150 of FIG. 10).

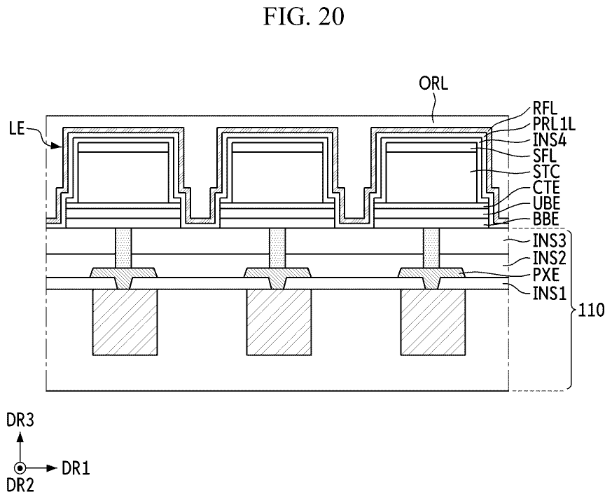

Referring to FIG. 20, an organic layer ORL covering the light-emitting elements LE may be formed.

For example, the organic layer ORL is applied to cover the light-emitting elements LE. The organic layer ORL may cover the top surface of the light-emitting elements LE.

In one or more other embodiments, the organic layer ORL may be formed between the light-emitting elements LE. For example, a filler may be applied between the light-emitting elements LE to fill the organic layer ORL between the light-emitting elements LE.

In one or more embodiments, when the display device 10 further includes a second through-electrode TRE2 in the non-display area NDA and a trench TR located in the display area DA, as shown in FIG. 9, the second through-electrode TRE2 and the trench TR may be formed after the organic layer ORL is formed. For example, a through-hole penetrating the organic layer ORL in the non-display area NDA is formed using a mask, and a groove is formed in the organic layer ORL between the light-emitting elements LE in the display area DA. By filling the through-hole and groove formed in this manner with a conductive material, the second through-electrode TRE2 and the trench TR may be formed. The conductive material may be a material having a lower resistivity than the common electrode. Accordingly, the IR drop of the common electrode may be reduced or minimized.

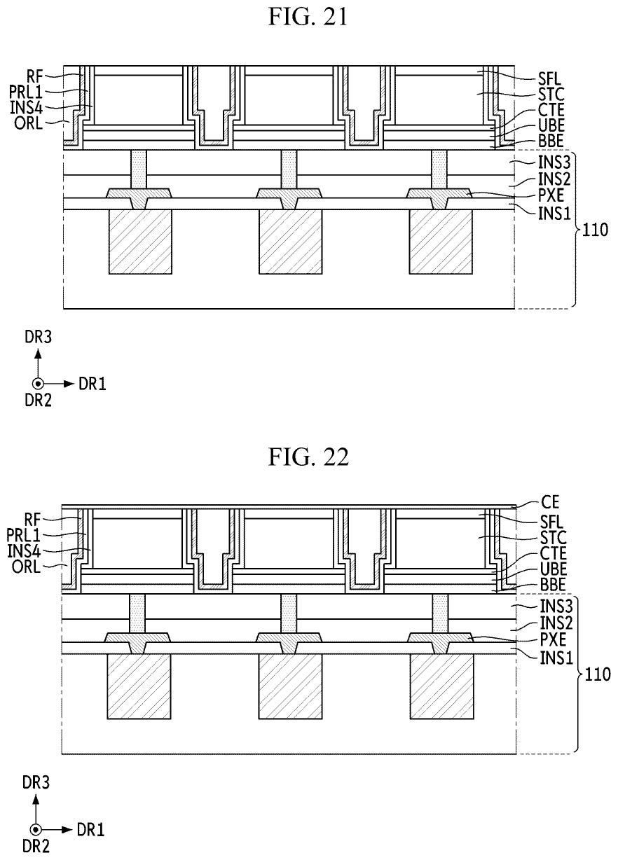

As shown in FIG. 21, the top surface of the light-emitting element LE is exposed through a polishing process, such as a chemical mechanical polishing (CMP) process and/or an etching process. At this time, the reflective layer RFL, the first protective layer PRL1, the element-insulating layer INS4, and the organic layer ORL on the top surface of the light-emitting element LE are etched by a known process until the top surface of the etching stop layer SFL is exposed. Accordingly, the top surface of the light-emitting element LE may be completely exposed. By this process, one end of the element insulating film INS4, the first protective layer PRL1, and the reflective layer RFL surrounding the side surface of the light-emitting element LE may be located without a step on the top surface of the light-emitting element LE.

In this way, when the light-emitting element LE is completely exposed through the polishing process, a separate mask is not required.

A common electrode CE is formed on the top surface of the light-emitting element LE (S150 of FIG. 10).

As shown in FIG. 22, the common electrode CE forms a common electrode CE on top of the planarized organic layer ORL and the light-emitting element LE.

The common electrode CE may include a transparent conductive oxide (TCO), such as indium tin oxide (ITO) or indium zinc oxide (IZO).

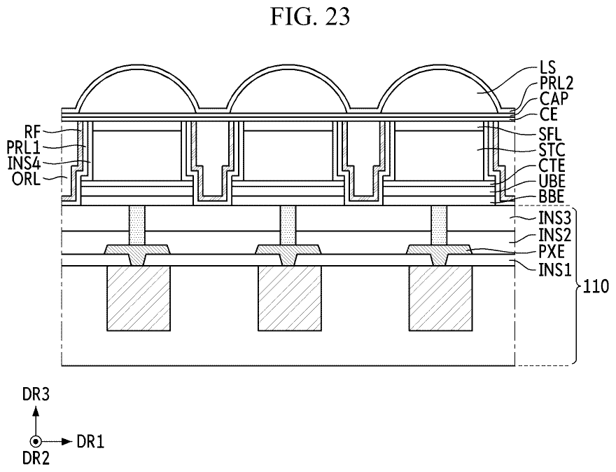

In one or more embodiments, when a display panel 100 including a light conversion layer and/or a color filter layer is to be manufactured, as shown in FIG. 23, a process of forming a light conversion layer and/or a color filter layer on top of or above the light-emitting element layer 120 or inside the light-emitting element layer 120 may be additionally performed.

In one or more embodiments, when manufacturing a display panel 100 including a lens-shaped optical structure LS as shown in FIG. 3, a process of attaching and/or forming a lens-shaped optical structure LS and a second protective layer PSV2 on a light-emitting element layer 120 may be additionally performed.

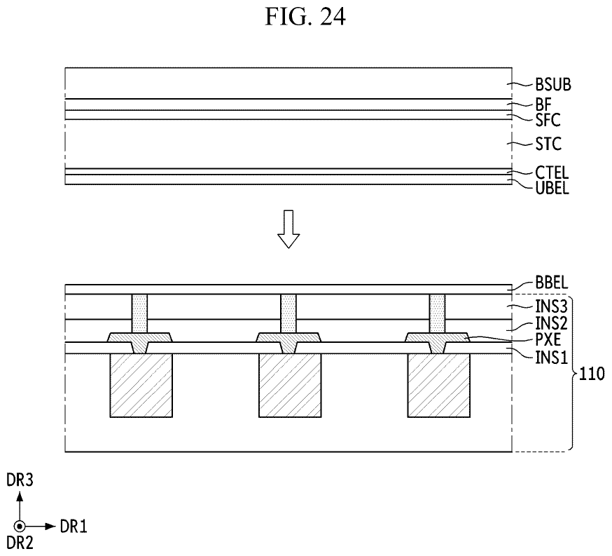

FIG. 24 is drawings to illustrate a method for manufacturing a display panel according to one or more other embodiments.

Referring to FIG. 24, a semiconductor stack STC is formed on a base substrate BSUB.

An AlGaN/GaN double heterostructure may be formed on a buffer layer BF of the base substrate BSUB. For example, an AlGaN layer may be formed on the buffer layer BF, and then a GaN-based semiconductor stack STC may be formed. The AlGaN layer may later serve as an etch-stop layer SFL.

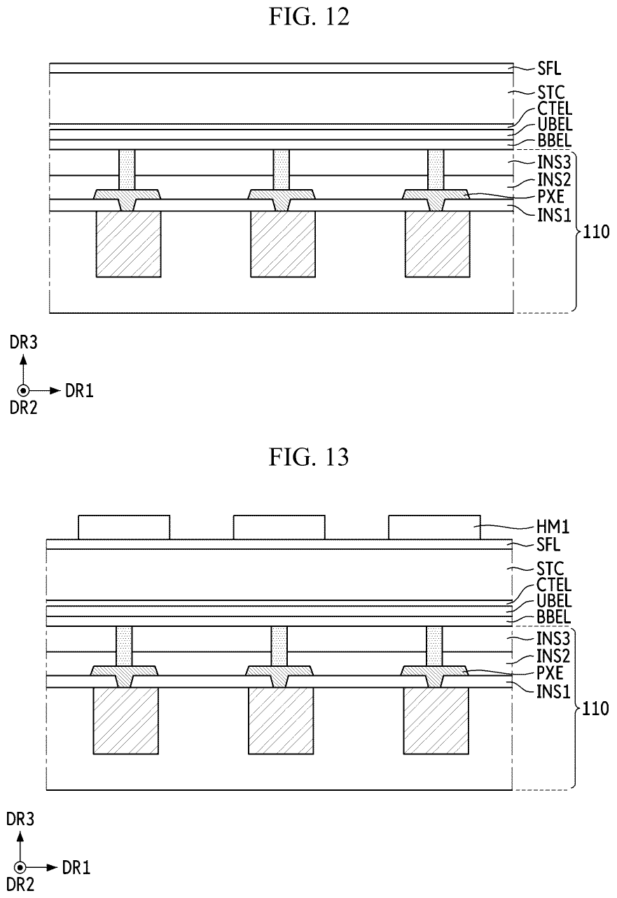

Thereafter, in S110 of FIG. 10, as described with reference to FIGS. 11 and 12, after bonding the base substrate BSUB to the backplane substrate 110, the base substrate BSUB is removed. Then, the buffer layer BF is polished and removed until the AlGaN layer as a separate etch-stop layer SFL is fully exposed. Then, the process proceeds to operation S120 without forming a separate etch-stop layer SFL.

A mask is formed and etched to divide the semiconductor stack STC.

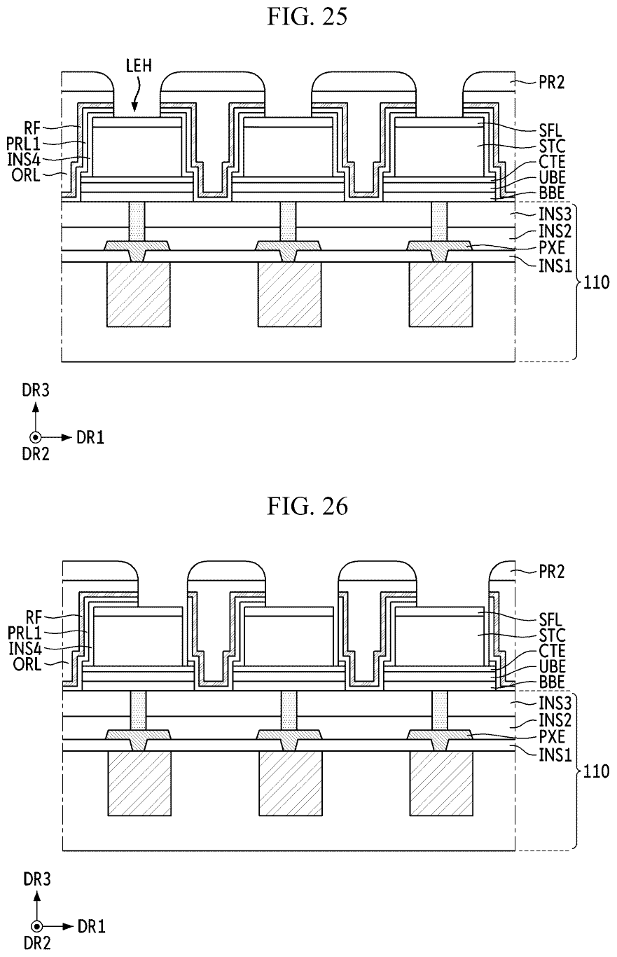

FIGS. 25 and 26 are cross-sectional views to illustrate one or more other embodiments of operations S140 and S150 of FIG. 10.

Referring to FIG. 25, the operation S140 and S150 of FIG. 10 described with reference to FIGS. 20 to 22 are different in that a through-hole LEH is formed penetrating the element-insulating layer INS4, the first protective layer PRL1, the reflective layer RF, and the organic layer ORL laminated on the top portion of the light-emitting element LE. The common electrode CE and the light-emitting element LE are connected through the through hole LEH.

For example, a photoresist mask PR is formed on the organic layer ORL. The photoresist mask PR may not overlap at least a portion of the top surface of the light-emitting element LE. The element-insulating layer INS4, the first protective layer PRL1, the reflective layer RF, and the organic layer ORL where the photoresist mask PR is not formed may be etched to expose the top surface of the light-emitting element LE. Even in this case, if the contact electrode CTE is located on the top surface of the light-emitting element LE, it may serve as an etching stop layer SFL. The top surface of the light-emitting element LE exposed in this way may contact the common electrode CE.

On the other hand, if the photoresist mask PR is misaligned, and does not sufficiently overlap the side surface of the semiconductor stack STC, the element-insulating layer INS4 may be etched on the side surface of the semiconductor stack STC, causing a problem in which the side surface of the semiconductor stack STC is exposed and damaged.

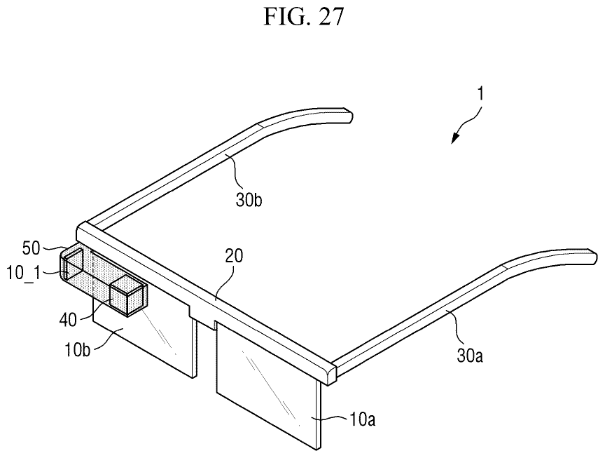

FIG. 27 is a drawing illustrating a virtual reality device 1 including a display device 10_1 according to one or more embodiments.

Referring to FIG. 27, the virtual reality device 1 according to one or more embodiments may be a device in the form of glasses. The virtual reality device 1 according to one or more embodiments may include a display device 10_1, a left-eye lens 10a, a right-eye lens 10b, a support frame 20, eyeglass frame legs 30a and 30b, a reflective member 40, and a display device storage unit 50.

While FIG. 27 illustrates a virtual reality device 1 including eyeglass frame legs 30a and 30b, the virtual reality device 1 according to one or more embodiments may be adapted to a head-mounted display including a head-mounted band that may be mounted on the head instead of eyeglass frame legs 30a and 30b. For example, the virtual reality device 1 according to one or more embodiments is not limited to the form shown in FIG. 25 and may be applied in various forms to various other electronic devices.

The display device storage unit 50 may include a display device 10_1 and a reflective member 40. The image displayed on the display device 10_1 may be reflected from the reflective member 40 and provided to the user's right eye through the right-eye lens 10b. As a result, the user may view the virtual reality image displayed on the display device 10_1 through the right eye.

In FIG. 27, the display device storage unit 50 is located at the right end of the support frame 20, but the embodiments are not limited thereto. For example, the display device storage unit 50 may be located at the left end of the support frame 20, and in this case, the image displayed on the display device 10_1 may be reflected from the reflective member 40 and provided to the user's left eye through the left-eye lens 10a. As a result, the user may view the virtual reality image displayed on the display device 10_1 through the left eye. Alternatively, the display device storage unit 50 may be located at both the left end and the right end of the support frame 20, in which case the user may view the virtual reality image displayed on the display device 10_1 through both the left and right eyes.

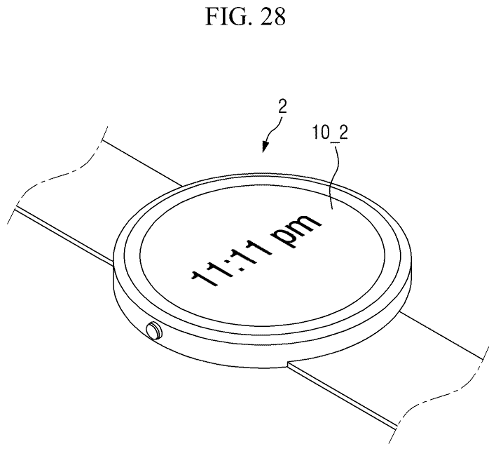

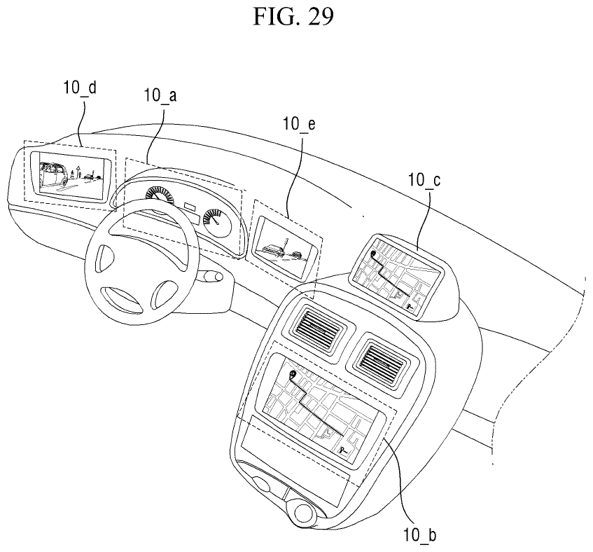

FIG. 28 is a drawing illustrating a smart device including a display device 10_2 according to one or more embodiments.

Referring to FIG. 28, the display device 10_2 according to one or more embodiments may be applied to a smart watch 2, which is one of the smart devices. The planar shape of the clock display unit of the smart watch 2 may follow the planar shape of the display device 10_2. For example, when the display device 10_2 according to one or more embodiments has a circular or oval planar shape, the clock display unit of the smart watch 2 may have a circular or oval planar shape. Alternatively, when the display device 10_2 according to one or more embodiments has a rectangular planar shape, the clock display unit of the smart watch 2 may have a rectangular planar shape. However, the embodiments are not limited thereto, and the clock display unit of the smartwatch 2 may not follow the flat form of the display device 10_2.

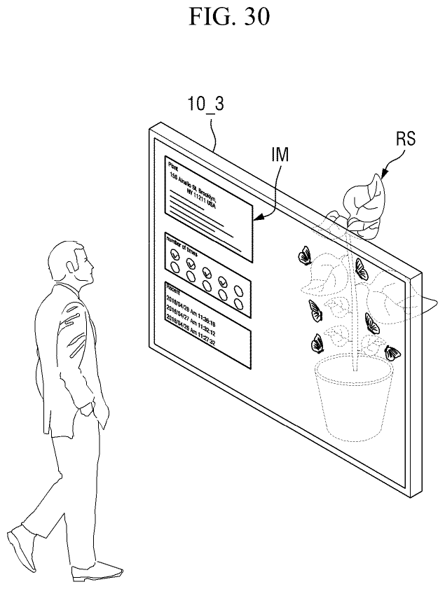

FIG. 29 is a drawing illustrating an automobile instrument panel and center fascia including display devices 10_a, 10_b, 10_c, 10_d, and 10_e according to one or more embodiments. FIG. 29 illustrates an automobile to which display devices 10_a, 10_b, 10_c, 10_d, and 10_e according to one or more embodiments are applied.

Referring to FIG. 29, the display devices 10_a, 10_b, 1 and 10_c according to one or more embodiments may be applied to an automobile instrument panel, applied to a center fascia of an automobile, or applied to a center information display (CID) located on a dashboard of an automobile. Alternatively, the display devices 10_d and 10_e according to one or more embodiments may be applied to a room mirror display that replaces a side mirror of an automobile.

FIG. 30 is a drawing illustrating a transparent display device including a display device 10_3 according to one or more embodiments.

Referring to FIG. 30, the display device 10_3 according to one or more embodiments may be applied to a transparent display device. The transparent display device may display an image IM and transmit light at the same time. Accordingly, a user positioned at the front of the transparent display device may not only view the image IM displayed on the display device 10_3, but also view an object RS or background positioned at the back of the transparent display device. When the display device 10_3 is applied to the transparent display device, the display panel 100 may include a light transmitting portion that may transmit light or may be formed on a substrate member formed of a material that may transmit light.

It should be understood, however, that the aspects of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
connection electrodes above the substrate;
light-emitting elements respectively above the connection electrodes, and comprising:
a semiconductor stack comprising a first semiconductor layer, an active layer, and a second semiconductor layer;
an etch-stop layer above the semiconductor stack; and
an insulating layer surrounding a side surface of the semiconductor stack in plan view, and having one end substantially level with a top surface of the etch-stop layer; and
a common electrode above the light-emitting elements.

2. The display device of claim 1, wherein the etch-stop layer comprises Indium Tin Oxide (ITO), Indium Zinc Oxide (IZO), or a transparent conductive material.

3. The display device of claim 1, wherein the etch-stop layer comprises AlGaN.

4. The display device of claim 1, further comprising a protective layer surrounding the light-emitting elements, the connection electrodes, and the insulating layer in plan view; and
a reflective layer surrounding the light-emitting elements, the connection electrodes, and the protective layer in plan view.

5. The display device of claim 4, wherein one end of the protective layer and one end of the reflective layer are substantially level with a top surface of the etch-stop layer.

6. The display device of claim 4, further comprising a trench contacting the common electrode between respective ones of the light-emitting elements so as not to overlap the light-emitting elements.

7. The display device of claim 6, wherein the trench comprises a material having a lower resistivity than the common electrode.

8. The display device of claim 7, wherein the substrate comprises a display area and a non-display area,
wherein the common electrode is commonly connected to the light-emitting elements, and
wherein the display device further comprises:
a common connection electrode comprising a same material as the connection electrode at the non-display area of the substrate; and
a through electrode electrically between the common connection electrode and the common electrode, connected to the common connection electrode, and comprising a same material as the trench.

9. The display device of claim 1, wherein the connection electrodes comprise a first connection electrode and a second connection electrode.

10. The display device of claim 1, wherein the light-emitting elements further comprise a contact electrode between the connection electrodes and the semiconductor stack.

11. The display device of claim 1, further comprising a lens-shaped optical structure above the light-emitting elements and the common electrode.

12. A method of manufacturing a display device comprising:
bonding a backplane substrate comprising a first connection electrode layer with a base substrate having a second connection electrode layer and a semiconductor stack;
forming an etch-stop layer on a top surface of the semiconductor stack;
etching and dividing the semiconductor stack and the etch-stop layer using a first mask;
forming an element-insulating layer covering a top surface of the etch-stop layer and a side surface of the semiconductor stack;
polishing a top surface of the base substrate to expose an entire surface of one side of the etch-stop layer; and
forming a common electrode above the semiconductor stack.

13. The method of claim 12, further comprising forming a protective layer covering the element-insulating layer; and
forming a reflective layer covering the protective layer.

14. The method of claim 13, wherein exposing the entire surface of the one side of the etch-stop layer comprises etching the element-insulating layer, the protective layer, and the reflective layer above a top surface of the semiconductor stack by a chemical mechanical polishing (CMP) process.

15. The method of claim 14, wherein the polishing the top surface of the base substrate comprises:
forming an organic layer surrounding light-emitting elements in plan view;
planarizing the light-emitting elements; and
forming a through electrode penetrating the organic layer, and electrically connected to a common connection electrode in a non-display area of the base substrate.

16. The method of claim 15, the forming the through electrode comprises forming a groove between respective ones of the light-emitting elements in the display area of the base substrate, and filling the groove with a material having a lower resistivity than the common electrode to form a trench.

17. The method of claim 12, wherein the etch-stop layer comprises Indium Tin Oxide (ITO), Indium Zinc Oxide (IZO), or a transparent conductive material.

18. The method of claim 12, wherein the bonding the backplane substrate with the base substrate comprises:
forming the first connection electrode layer on the backplane substrate;
forming the second connection electrode layer on the semiconductor stack of the base substrate;
arranging the first connection electrode layer and the second connection electrode layer to be in contact;
bonding the first connection electrode layer and the second connection electrode layer; and
removing the base substrate from the semiconductor stack.

19. The method of claim 12, further comprising forming a lens-shaped optical structure above light-emitting elements, which comprise the etch-stop layer and the semiconductor stack, and a light-emitting element layer, which comprises the common electrode.

20. A method of manufacturing a display device comprising:
bonding a backplane substrate comprising a first connection electrode layer, and a base substrate comprising a second connection electrode layer, a semiconductor stack, and an etch-stop layer;
etching and dividing the semiconductor stack and the etch-stop layer using a first mask;
forming an element-insulating layer to cover a top surface of the etch-stop layer and a side surface of the semiconductor stack;
polishing a top surface of the base substrate to expose an entire surface of one side of the etch-stop layer; and
forming a common electrode above the semiconductor stack,
wherein the etch-stop layer and the semiconductor stack comprise an AlGaN/GaN double heterostructure.

21. An electronic device comprising a display device for displaying an image, the display device comprising:
a substrate;
connection electrodes above the substrate;
light-emitting elements respectively above the connection electrodes, and comprising:
a semiconductor stack comprising a first semiconductor layer, an active layer, and a second semiconductor layer;
an etch-stop layer above the semiconductor stack; and
an insulating layer surrounding a side surface of the semiconductor stack in plan view, and having one end substantially level with a top surface of the etch-stop layer; and
a common electrode above the light-emitting elements.
